(19) United States
(12) Patent Application Publication
(10) Pub. No.: US 2026/0352182 A1
(43) Pub. Date: Nov. 5, 2026

(54) PIEZOELECTRIC RESONATOR, METHOD FOR USE, AND MULTIVARIABLE SENSOR

(71) Applicant: WIKA Alexander Wiegand SE & Co. KG, Klingenberg/Main (DE)

(72) Inventor: Fabian PFEIFER, Elsenfeld (DE)

(73) Assignee: WIKA Alexander Wiegand SE & Co. KG, Klingenberg/Main (DE)

(21) Appl. No.: 19/663,145

(22) Filed: Apr. 29, 2026

(30) Foreign Application Priority Data
Apr. 30, 2025 (DE) 10 2025 116 829.6

(51) Int. Cl. H03H 9/13; H03H 9/215; G01R 19/00; G01R 27/26

(52) U.S. Cl. CPC H03H 9/131; H03H 9/215; G01R 19/0084; G01R 27/2605

(57) ABSTRACT

A piezoelectric resonator having a piezoelectric substrate with a base section and an excitation section, as well as an electrode structure that is arranged, at least in sections, at or in the excitation section. The electrode structure further includes a first multifunctional electrode having a first main contact and a first auxiliary contact. The invention also encompasses a multivariable sensor having a piezoelectric resonator, and a method for use of a piezoelectric resonator.

This nonprovisional application claims priority under 35 U.S.C. § 119(a) to German Patent Application No. 10 2025 116 829.6, which was filed in Germany on Apr. 30, 2025, and which is herein incorporated by reference.

### BACKGROUND OF THE INVENTION

### Field of the Invention

Piezoelectric resonator, method for use for such a piezoelectric resonator, and multivariable sensor having such a piezoelectric resonator

### Description of the Background Art

Piezoelectric resonators are important components in numerous electronic devices, in particular oscillators and filters. These resonators make use of the piezoelectric properties of certain materials in order to convert mechanical vibrations into electrical signals, and vice versa.

In the past, piezoelectric resonators have been developed primarily in the form of crystal resonators and ceramic resonators. These resonators are characterized by their high stability and precision, which make them ideal for applications in communication, the automotive industry, medical technology, and measurement technology.

One important area of development is the integration of piezoelectric resonators into microelectromechanical systems (referred to below as MEMSs for short). MEMS resonators offer the advantage of a miniaturized design and can be used in numerous applications, for example sensor systems. The manufacture and qualification of these resonators require advanced manufacturing techniques and test methods to ensure their performance and reliability.

In sensor systems, piezoelectric resonators are widely used in particular for measuring the density and viscosity in liquid media. These sensors are able to perform precise measurements by initially exciting the resonator into mechanical vibration in order to subsequently analyze the vibration behavior and in particular the decay behavior of this vibration. This may be used to precisely detect changes in the density and/or viscosity of the surrounding medium. Such sensors are often used in industrial applications, for example for monitoring the quality of oil in machines and mobile work machines. As a result of continuously monitoring the density and viscosity of oils, maintenance intervals may be optimized and downtimes may be reduced.

Despite the advances in technology, there are still challenges in optimizing the functionality and versatility of piezoelectric resonators.

### SUMMARY OF THE INVENTION

It is therefore an object of the present invention to address these challenges by providing a piezoelectric resonator having an innovative electrode structure. A second aspect of the invention relates to a method for using a piezoelectric resonator. A third aspect of the invention relates to the use of a piezoelectric resonator in a multivariable sensor. Advantageous examples and refinements of the various aspects of the invention are likewise the subject matter of the dependent claims.

According to the first aspect of the invention, a piezoelectric resonator includes a piezoelectric substrate having a base section and an excitation section, and an electrode structure that is arranged, at least in sections, at or in the excitation section.

A substrate refers to a body made of a piezoelectric material whose extension in a spatial direction, referred to below as the height or thickness of the substrate, is less than an extension in the two spatial directions perpendicular thereto, which are referred to below as the length and width of the substrate. When reference is made below to the length of the piezoelectric substrate, this is intended to mean the spatial direction of extension of the substrate that corresponds essentially to an extension of the substrate from the base section to the excitation section. In examples, the thickness of the substrate may be between 100 and 350 microns, while the width may be between 300 and 750 microns and the length may be between 2500 and 10,000 microns. High stability may be combined with good vibration characteristics by appropriate dimensioning.

Within the meaning of the present document, an electrode structure refers to the totality of all strip conductors, electrodes, contacts, and other electronic structures that are possibly encompassed by a particular example of the piezoelectric resonator.

The base section is configured to be connected to further components, for example to a support or a housing of a higher-order unit, such as a multivariable sensor that is described in greater detail below.

Furthermore, electrical contacts, in particular contact pads, of the electrode structure may be arranged at an edge of the base section facing away from the excitation section, so that the electrical contacts are available in a spatially concentrated manner for simple, reliable contacting.

In the context of the arrangement of the electrode structure relative to the excitation section, "at least in sections" means that the extension of the electrode structure in the direction of the length of the piezoelectric substrate overlaps with same in such a way that a non-vanishing sectional area results between the electrode structure and the excitation section. This allows the excitation section of the piezoelectric substrate to be effectively excited into mechanical vibration by parts, in particular electrodes, of the electrode structure. The electrode structure preferably overlaps with at least 25 percent of the length, preferably with at least 50 percent of the length, particularly preferably with essentially the entire length of the excitation section.

The statement that the electrode structure is arranged "at or in" the excitation section (at least in sections) means that various techniques may be used to connect the electrode structure to the piezoelectric substrate or to integrate it into same. When the electrode structure is arranged "at" the excitation section (at least in sections), this means that the electrode structure is applied to a surface of the piezoelectric substrate. For example, methods such as physical vapor deposition (PVD) from the group of thin film technologies are suitable for such an arrangement. In contrast, an arrangement (at least in sections) "in" the piezoelectric substrate may mean that the electrode structure is embedded in the body of the substrate, for example by countersinking the electrode structure into the surface of the substrate body. Doping processes, for example, are suitable for this purpose. Likewise within the meaning of the present invention, an arrangement of an electrode structure between two joined sublayers of a substrate made up of multiple layers is understood as an arrangement "in" the substrate.

According to the invention, the electrode structure of the piezoelectric resonator includes a first multifunctional electrode.

While conventional electrodes, as used in the prior art for electrical charge transport between the excitation sections and a control electronics system, have only a single contact, for which reason they are also referred to below as a "single contact," the first multifunctional electrode has a first main contact and a first auxiliary contact. The first main contact and the first auxiliary contact may in principle have the same design, but are not directly short-circuited to one another, and instead are electrically separated from one another by the multifunctional electrode, or only resistively, inductively, or capacitively coupled to one another by the multifunctional electrode.

In other words, by means of the first main contact and the first auxiliary contact it is possible to carry out various electronic measurement and/or operating functions, using the multifunctional electrode, which go far beyond simple application of a potential or an excitation signal, as is done in the prior art using conventional electrodes. For example, it is thus possible to perform a voltage measurement and/or a resistance measurement between the first main contact and the first auxiliary contact, and/or a capacitance measurement at the first multifunctional electrode. It is likewise possible, for example, to conduct a heating current or a test current between the first main contact and the first auxiliary contact by use of the first multifunctional electrode.

Depending on the specific configuration of the first multifunctional electrode, it is thus possible, as explained in greater detail in subsequent examples, to implement a plurality of additional measurement tasks or operating functions, so that the piezoelectric resonator may be used in a versatile and multifunctional manner, and at the same time a high degree of integration and miniaturization is achievable.

When reference is made here and in the following discussion to certain elements, assemblies, or functional units as "first" in each case, this is solely for the purpose of unambiguous designation. That is, such a reference is not to be construed as limiting. Likewise, this reference does not imply the presence or nonpresence of further elements, assemblies, or functional units of the same type. Thus, it is neither implied nor precluded by the designation "first functional electrode" that a "second functional electrode" must or may also be present. At the same time, as a result of the first multifunctional electrode including the "first main contact" and the "first auxiliary contact," it is neither implied nor precluded that they have even further contacts.

In an example of the first aspect of the invention, the electrode structure includes a first single functional electrode having a first single contact, and a second single functional electrode having a second single contact.

When reference is made below to a "second" element, assembly, or functional unit, this is solely for the purpose of unambiguous designation. That is, such references are likewise not to be construed as limiting. Likewise, none of these references implies the presence or nonpresence of further elements, assemblies, or functional units of the same type.

Thus, a further designation of a "second single functional electrode" neither implies nor precludes that even further functional electrodes must or may be present.

The first single functional electrode and the second single functional electrode may correspond, for example, to conventional electrodes as used in the prior art for excitation of piezoelectric resonators. They have only a single contact, which is sufficient for application of a potential or excitation signal. To clearly express that they have only a single contact, they are in each case referred to as a "single contact." In contrast to the first multifunctional electrode, these conventional electrodes are also referred to as "single functional" in order to clarify that they are not suited or designed for carrying out certain electronic measurement and/or operating functions that go beyond the stated simple application of a potential or an excitation signal.

The first single functional electrode and the second single functional electrode are each arranged, at least in sections, at or in the excitation section, while the first multifunctional electrode in this example is arranged at any given location at the piezoelectric substrate, for example completely at or in the base section or also, at least in sections, at or in the excitation section. The phrases "at least in sections" and "at or in" analogously express in each case what is explained above concerning corresponding phrases in the context of the arrangement of the electrode structure relative to the excitation section.

In this example, as a result of two single functional electrodes, namely, the first single functional electrode and the second single functional electrode, being present and arranged, at least in sections, at or in the excitation section, the excitation section of the piezoelectric substrate may already be excited into mechanical vibration by applying an excitation signal in each case to the first single contact and the second single contact. However, if required by the geometry of the substrate, possibly in conjunction with material properties of the selected piezoelectric material of the substrate, or a requirement for the type or quality of the vibrations, in this example it is not ruled out for the electrode structure to include even further single functional electrodes, which likewise may take part in the vibration excitation.

However, in this example the first multifunctional electrode does not take part in the excitation of vibrations in the area of the excitation section, and therefore may be contacted at any time via the first main contact and the first auxiliary contact for the purpose of carrying out various measurement or operating functions. Therefore, it also does not matter whether the first multifunctional electrode is arranged, at least in sections, at or in the excitation section.

The piezoelectric resonator according to this example combines reliable vibration excitation and analysis of the excitation section with a plurality of additional measurement and operating functions that may be carried out concurrently with the first multifunctional electrode for vibration excitation or analysis.

In a further example of the first aspect of the invention, in addition to the first multifunctional electrode the electrode structure also includes a first single functional electrode having a first single contact. Both the first single functional electrode and the first multifunctional electrode are arranged, at least in sections, at or in the excitation section. The phrases "at least in sections" and "at or in" analogously express in each case what is explained above concerning corresponding phrases in the context of the arrangement of the electrode structure relative to the excitation section.

Also in this example, as a result of two electrodes, namely, the first single functional electrode and the first multifunctional electrode, being present and arranged, at least in sections, at or in the excitation section, the excitation section of the piezoelectric substrate may already be excited into mechanical vibration by applying an excitation signal in each case to the first single contact of the first single functional electrode and to the first main contact and/or the first auxiliary contact of the first multifunctional electrode. However, if required by the geometry of the substrate, possibly in conjunction with material properties of the selected piezoelectric material of the substrate, or a requirement for the type or quality of the vibrations, in this example it is not ruled out for the electrode structure to include even further single functional electrodes or further multifunctional electrodes, which likewise may take part in the vibration excitation.

In this example, the first multifunctional electrode is thus assigned two functions which may be associated with various manners of operation or use of the piezoelectric resonator:

In a first manner of use, which may also be referred to below as dynamic use or as dynamic operation, the first multifunctional electrode directly takes part in the excitation of vibrations in the area of the excitation section. For this purpose, an excitation signal may be applied to the first multifunctional electrode via the first main contact, wherein at the first auxiliary contact, either the same excitation signal is concurrently applied or the first auxiliary contact is concurrently electrically insulated from the excitation signal.

In a second manner of use, which may also be referred to below as static use or as static operation, a plurality of additional measurement tasks or operating functions may be carried out using the multifunctional electrode. For this purpose, the multifunctional electrode is contacted via the first main contact and the first auxiliary contact, and for example a voltage measurement, a resistance measurement, and/or a capacitance measurement are/is performed at the first multifunctional electrode, between the first main contact and the first auxiliary contact. Likewise, the multifunctional electrode may be electrically activated, for example by conducting a heating current or a test current through the first multifunctional electrode via the first main contact and the first auxiliary contact.

The piezoelectric resonator according to this example combines reliable vibration excitation and analysis of the excitation section with a plurality of additional measurement and operating functions that can be carried out using the first multifunctional electrode. In contrast to the above-mentioned example, the vibration excitation and analysis cannot be performed in parallel, i.e., concurrently, with the additional measurement and/or operating functions. For this purpose the total number of necessary conventional or single functional electrodes that must be arranged, at least in sections, at or in the excitation section may be reduced. A higher degree of miniaturization and integration with practically the same multifunctionality is thus achievable.

In a further example of the first aspect of the invention, in addition to the first multifunctional electrode the electrode structure also includes a second multifunctional electrode having a second main contact and a second auxiliary contact. Both the first multifunctional electrode and the second multifunctional electrode are thus each arranged, at least in sections, at or in the excitation section. The phrases "at least in sections" and "at or in" analogously express in each case what is explained above concerning corresponding phrases in the context of the arrangement of the electrode structure relative to the excitation section. The above discussion regarding function, design, wiring, possible advantages, possible uses, and with regard to differentiation from conventional (single functional) electrodes in the context of the first multifunctional electrode, the first main contact, and/or the first auxiliary contact analogously applies to the second multifunctional electrode, the second main contact, and the second auxiliary contact.

Also in this example, as a result of two multifunctional electrodes, namely, the first multifunctional electrode and the second multifunctional electrode, being present and arranged, at least in sections, at or in the excitation section, the excitation section of the piezoelectric substrate may already be excited into mechanical vibration by applying an excitation signal in each case to the first main contact and/or the first auxiliary contact of the first multifunctional electrode and to the second main contact and/or the second auxiliary contact of the second multifunctional electrode. However, if required by the geometry of the substrate, possibly in conjunction with material properties of the selected piezoelectric material of the substrate, or a requirement for the type or quality of the vibrations, in this example it is not ruled out for the electrode structure to additionally include even further single functional electrodes or further multifunctional electrodes, which likewise may take part in the vibration excitation.

In this example, both the first multifunctional electrode and the second multifunctional electrode are thus assigned two functions which may be associated with two different manners of operation or use of the piezoelectric resonator, namely, dynamic use and static use.

The dynamic use or static use discussed in the context of the preceding example likewise analogously applies to the first multifunctional electrode and the second multifunctional electrode.

The same as with the above-mentioned example, the piezoelectric resonator according to this example combines reliable vibration excitation and analysis of the excitation section with a plurality of additional measurement and operating functions that may be carried out using the first multifunctional electrode and the second multifunctional electrode. In particular, in this example the first multifunctional electrode and the second multifunctional electrode may be used to concurrently carry out different measurement and operating functions, as a result of which the piezoelectric resonator may be used in an even more versatile manner. Likewise, the total necessary number of conventional or single functional electrodes that must be arranged, at least in sections, at or in the excitation section may be even further reduced. A higher degree of miniaturization and integration, and at the same time high multifunctionality, is thus achievable.

In a further example of the first aspect of the invention, in addition to the first multifunctional electrode and the second multifunctional electrode from the preceding example, the electrode structure also includes a third multifunctional electrode having a third main contact and a third auxiliary contact, and a fourth multifunctional electrode having a fourth main contact and a fourth auxiliary contact. The first multifunctional electrode, the second multifunctional electrode, the third multifunctional electrode, and the fourth multifunctional electrode are each arranged, at least in sections, at or in the excitation section. The phrases "at least in sections" and "at or in" analogously express in each case what is explained above concerning corresponding phrases in the context of the arrangement of the electrode structure relative to the excitation section. The above discussion regarding function, design, wiring, possible advantages, possible uses, and with regard to differentiation from conventional (single functional) electrodes in the context of the first multifunctional electrode, the first main contact, and/or the first auxiliary contact analogously applies to the second, third, and fourth multifunctional electrodes, to the second, third, and fourth main contacts, and to the second, third, and fourth auxiliary contacts.

When reference is made here and in the following discussion to certain elements, assemblies, or functional units as "third" and/or "fourth" in each case, this is solely for the purpose of unambiguous designation. That is, such a reference is not to be construed as limiting. Likewise, this reference does not imply the presence or nonpresence of further elements, assemblies, or functional units of the same type. Thus, it is neither implied nor precluded by the designation "third functional electrode" that further multifunctional electrodes must or may also be present. At the same time, as a result of the third multifunctional electrode including the "third main contact" and the "third auxiliary contact," it is neither implied nor precluded that they have even further contacts. Rather, the designation "third main/auxiliary contact" is used here to unambiguously associate these contacts with the "third" multifunctional electrode.

The piezoelectric substrate may have the shape of a tuning fork, for example, and the excitation section may include a first tine and a second tine. The first multifunctional electrode and the second multifunctional electrode may be arranged, at least in sections, in or at the first tine, while the third multifunctional electrode and the fourth multifunctional electrode may be arranged, at least in sections, in or at the second tine. By means of an appropriate design the piezoelectric resonator may be precisely excited into vibration, while a high degree of miniaturization, integration, and multifunctionality is achieved. Furthermore, the number of conventional or single functional electrodes that must be arranged, at least in sections, at or in the excitation section may be greatly reduced.

Likewise, at least the first and second multifunctional electrodes, for example also the third and fourth multifunctional electrodes, may each be arranged at or in different surfaces of the piezoelectric substrate. For example, the first multifunctional electrode and/or the third multifunctional electrode may be arranged at or in a first surface of the substrate, while the second multifunctional electrode and/or the fourth multifunctional electrode may be arranged at or in a second surface of the substrate. The first surface and the second surface are arranged opposite one another. For example, the first surface forms a front side, and the second surface forms a rear side, of the piezoelectric resonator.

The phrases "at least in sections" and "at or in" analogously express in each case what is explained above concerning the corresponding phrases "at least in sections" or "at or in" in the context of the arrangement of the electrode structure relative to the excitation section. By use of such a design the particular multifunctional electrodes may have a particularly large surface area, so that they may be effectively used for excitation and/or analysis of vibrations of the excitation section. Furthermore, as a result of the large-surface design of the electrodes, improved sensitivity and measuring accuracy may be achieved when carrying out additional measurement or operating functions (in the above-mentioned static operation, for example). In addition, manufacture of the piezoelectric resonator may be facilitated.

The multifunctional electrodes, i.e., the first multifunctional electrode, the second multifunctional electrode, the third multifunctional electrode, and/or the fourth multifunctional electrode (summarized below as "the multifunctional electrodes"), present in each case in the preceding examples may each have at least one of the following examples.

Regardless of the number of multifunctional electrodes at the piezoelectric resonator, each multifunctional electrode may include a resistive track or a capacitor. Thus, many different combinations of resistive tracks and capacitors on or at the piezoelectric resonator may be conceivable, for example two or more capacitors, two or more resistive tracks, or at least one resistive track and at least one capacitor in each case. Further examples in this regard are described below.

For example, at least one of the multifunctional electrodes may have a resistive track that extends from a first end to a second end of the resistive track. The first end is electroconductively connected to a respective main contact of the particular multifunctional electrode, and the second end is electroconductively connected to a respective auxiliary contact of the particular multifunctional electrode, so that between the particular main contact and auxiliary contact, a resistance measurement may be performed at the resistive track, or current may be conducted through the resistive track.

The material from which the resistive track is made may have a temperature-dependent resistance, so that a temperature measurement may be enabled by performing a resistance measurement between a respective main contact and a respective auxiliary contact of the particular multifunctional electrode.

Likewise, the material from which the resistive track is made may also have a resistance that is a function of the concentration of a target medium in the surroundings of the resistive track. "In the surroundings" of the resistive track means that the target medium, in particular dissolved in a main medium, surrounds at least the excitation section of the piezoelectric resonator, and in particular is in direct contact with same. The target medium may be water, for example, while the main medium is an oil. By use of such an example, a concentration measurement, for example a moisture measurement, may be performed by means of a resistance measurement between a respective main contact and a respective auxiliary contact of the particular multifunctional electrode. For example, an excessive content of water in the motor oil or hydraulic oil may result in increased wear. A boundary area may be determined in a timely manner, and appropriate measures taken, by performing regular moisture measurements.

Alternatively or additionally, the resistive track may be designed as a heating resistor. This means that it is designed to be heated to a defined heating temperature when a heating current is conducted through it via a respective main contact and its respective auxiliary contact. The heating temperature may be specified in particular as a function of an existing ambient or media temperature (for example, 10 Kelvin higher than the media temperature), or may be set to an absolute value (for example, just under 100° Celsius). It is thus possible to implement various measurement and operating functions, which are explained in greater detail below based on examples.

The resistive track may have a meandering shape, regardless of what material the resistive track is made of and regardless of whether or not it is designed as a heating resistor. For the same surface area requirements, it is thus possible to greatly increase the length of the resistive track between the first end and the second end of the resistive track.

Furthermore, it may be provided that the resistive track covers at least 50 percent, preferably even at least 75 percent, of a surface of the excitation area, or, if the piezoelectric substrate has the shape of a tuning fork, of a surface of a tine of the substrate, so that the particular multifunctional electrode may be used particularly effectively for excitation and/or analysis of vibrations of the excitation section, and improved sensitivity and measuring accuracy may be achieved when carrying out additional measurement or operating functions.

In addition, at least one of the multifunctional electrodes may include a capacitor, for example.

The capacitor has a first capacitor electrode that is electrically connected to the respective main contact, and a second capacitor electrode that is electrically connected to the respective auxiliary contact.

The capacitor may be designed, for example, as an interdigital capacitor and provided on or in a surface of the excitation section and coated with an insulation layer or passivation layer. Alternatively, the capacitor may be designed as a parallel plate capacitor in which the first capacitor electrode is insulated from the second capacitor electrode by the piezoelectric substrate or a sublayer of the piezoelectric substrate, wherein both capacitor electrodes are electrically insulated from the surroundings of the piezoelectric resonator by sublayers of the substrate or by insulation layers. It is thus possible to perform a dielectricity measurement at a medium surrounding the piezoelectric resonator by means of a capacitance measurement between a respective main contact and a respective auxiliary contact of the particular multifunctional electrode.

Likewise, the capacitor may be designed as a parallel plate capacitor in which the first capacitor electrode is insulated from the second capacitor electrode by a dielectric intermediate layer. The material from which the dielectric intermediate layer is made may be selected in such a way that a dielectric constant of the dielectric intermediate layer is a function of the concentration of a target medium in the surroundings of the capacitor. "In the surroundings" of the capacitor means that the target medium, in particular dissolved in a main medium, surrounds at least the excitation section of the piezoelectric resonator, and in particular is in direct contact with same. The target medium may be water, for example, while the main medium is an oil.

By use of such an example, a concentration measurement, for example a moisture measurement, may be performed by means of a capacitance measurement between a respective main contact and a respective auxiliary contact of the particular multifunctional electrode. It may be provided that the first capacitor electrode, as a flat electrode, is arranged on or in a surface of the excitation section which is covered, at least in sections, by the intermediate layer, while the second capacitor electrode is arranged above the intermediate layer, facing the surroundings of the piezoelectric resonator. The second capacitor electrode may in particular have a comb structure, in particular a comb structure with lateral teeth between the comb tines, or a grid structure or a perforation, so that the intermediate layer is not completely concealed by the second capacitor electrode, and the target medium can effectively interact with the intermediate section.

As a result of the flat design of the first capacitor electrode, i.e., as a closed surface which as a lowest layer of the capacitor is arranged on or in a surface of the substrate, the particular multifunctional electrode may be used in a particularly effective manner for excitation and/or analysis of vibrations of the excitation section, and improved sensitivity and measuring accuracy may be achieved when carrying out additional measurement or operating functions. In particular, it may be provided that the flat first capacitor electrode covers at least 50 percent, preferably even at least 75 percent, of a surface of the excitation area, or, if the piezoelectric substrate has the shape of a tuning fork, of a surface of a tine of the substrate.

In a further example of the first aspect of the invention, the piezoelectric substrate is made of a quartz, in particular alpha-quartz. Alpha-quartz, as a material for the piezoelectric substrates, has a very high frequency stability, so that the piezoelectric resonator made therefrom may have very high quality. Very precise determination of the resonance frequency is thus possible. Furthermore, the substrate made of alpha-quartz, when the quartz is prepared by anisotropic etching processes in certain crystallographic directions or at certain cutting angles, may have a low thermal cross-sensitivity. In addition, anisotropic etching processes for quartz are very well controllable by process engineering, so that desired target shapes may be created with high precision and reliability.

In a further example of the first aspect of the invention, the piezoelectric substrate is made of a piezoelectric monocrystal or includes at least one such piezoelectric monocrystal, with lithium niobate (LiNbO3) in particular being mentioned. LiNbO3 has a higher piezoelectric coupling coefficient compared to the quartz mentioned above.

In a further example of the first aspect of the invention, the piezoelectric substrate has a one-piece design, i.e., is made from a single piece. The number of components and joints may thus be reduced, which on the one hand may lower manufacturing costs, and on the other hand may improve the vibration and measurement properties as well as the stability and resistance to mechanical, chemical, or other environmental stresses on the piezoelectric resonator, compared to the examples in which the substrate is formed from multiple joined layers or plies.

According to a second aspect of the invention, a method for use of a piezoelectric resonator according to the first aspect of the invention or according to one of the stated examples thereof includes the following steps, which may be carried out in any order, indirectly or directly in succession:
Step A: Performing an electrical measurement at the first multifunctional electrode between the first main contact and the first auxiliary contact, or electrically activating the first multifunctional electrode via the first main contact and the first auxiliary contact, and
Step B: Applying an excitation signal to the first multifunctional electrode via the first main contact, wherein at the first auxiliary contact, either the same excitation signal is concurrently applied or the first auxiliary contact is concurrently electrically insulated from the excitation signal.

Step A corresponds to the "static manner of use" of the piezoelectric resonator explained above, while step B corresponds to the "dynamic manner of use." Regardless of which step is carried out first, due to the indirect or direct sequence of the steps the piezoelectric resonator may be used in an automated, multifunctional, and thus versatile manner. The sequence of the steps may be carried out, for example, continuously in a periodic changeover, so that, for example, a plurality of measuring or operating tasks may be carried out continuously. An "indirect" sequence or an " indirect" execution in succession means that between the steps (regardless of which is carried out first), at least one different, further step is carried out. In contrast, if the steps follow in direct succession, this corresponds to a "direct" sequence or a "direct" execution in succession.

In an example of the second aspect of the invention, the first multifunctional electrode has a capacitor, and the electrical measurement in step A includes a capacitance measurement and/or voltage measurement.

If the capacitor is designed as an interdigital capacitor, or if the capacitor has a first capacitor electrode, and a second capacitor electrode that is insulated from the first capacitor electrode by the piezoelectric substrate or a sublayer of the piezoelectric substrate, a dielectricity measurement may be effectively performed at a medium surrounding the piezoelectric resonator, as explained above with regard to the first aspect of the invention.

If the capacitor is designed as a parallel plate capacitor in which a first capacitor electrode is insulated from a second capacitor electrode by a dielectric intermediate layer, and the material from which the dielectric intermediate layer is made is selected in such a way that a dielectric constant of the dielectric intermediate layer is a function of the concentration of a target medium in the surroundings of the capacitor, a concentration measurement may thus be effectively performed with regard to the target medium, as explained above with regard to the first aspect of the invention.

In a further example of the second aspect of the invention, the first multifunctional electrode has a resistive track, and the electrical measurement in step A includes a resistance measurement.

If the resistive track is made of a material having a temperature-dependent resistance, a temperature measurement may thus be effectively performed.

If the resistive track is made of a material having a resistance that is a function of the concentration of a target medium in the surroundings of the resistive track, a concentration measurement may thus be effectively performed with regard to the target medium, as explained above with regard to the first aspect of the invention.

In a further example of the second aspect of the invention, the first multifunctional electrode has a heating resistor, and the electrical activation in step A includes the conduction of a heating current through the heating resistor via the first main contact and the first auxiliary contact.

In this example in which the first multifunctional electrode has a heating resistor, by appropriate use the piezoelectric resonator may be temporarily heated by the heating resistor in a targeted manner. In this way the piezoelectric resonator may be baked out and cleaned, with impurities, (in particular organic) deposits, and the like being effectively removed from the surfaces of the piezoelectric resonator when it is heated.

At the same time, for many media the viscosity may be reduced by the heating. In particular when, following step A, in step B the excitation section of the piezoelectric resonator is excited into vibration, the removal of impurities and deposits from its surfaces may be achieved even more effectively.

The electrode structure may at the same time have a second multifunctional electrode, for example, which likewise is arranged, at least in sections, at or in the excitation section, and which has a second main contact and a second auxiliary contact, and which is designed as a parallel plate capacitor in which a first capacitor electrode is insulated from a second capacitor by a dielectric intermediate layer electrode, and the material from which the dielectric intermediate layer is made is selected in such a way that a dielectric constant of the dielectric intermediate layer is a function of the concentration of a target medium in the surroundings of the capacitor. The first multifunctional electrode is arranged, at least in sections, on or in a first surface of the piezoelectric substrate, and the second multifunctional electrode is arranged, at least in sections, on or in a second surface of the piezoelectric substrate opposite from the first surface. By use of such an arrangement, the second multifunctional electrode, and thus also the dielectric intermediate layer that it encompasses, may be heated in a targeted manner when the heating resistor in step A is electrically activated.

The heating effect may be achieved particularly effectively when the first multifunctional electrode and the second multifunctional electrode overlap one another, at least in sections, in a top view of one of the surfaces.

Due to the targeted heating, residues of the target medium which may possibly have accumulated in the dielectric intermediate layer may be effectively baked out, so that a precise measurement of the concentration of the target medium may once again be performed. This method has proven to be particularly useful when the target medium is water, i.e., when the second multifunctional electrode is designed as a moisture sensor. Effective bakeout of the dielectric intermediate layer may be achieved by heating to a heating temperature of just under 100° Celsius. Possible interfering influences on the moisture measurement may be minimized by baking out the water, so that the moisture sensor then once again allows a precise, error-reduced determination of the moisture.

In a further example of the second aspect of the invention, the first multifunctional electrode once again has a heating resistor, and the electrode structure additionally has a second multifunctional electrode, which likewise is arranged, at least in sections, at or in the excitation section and which has a second main contact and a second auxiliary contact. The second multifunctional electrode has a resistive track with a temperature-dependent resistance, and the first multifunctional electrode and the second multifunctional electrode are jointly arranged on or in a surface of the piezoelectric substrate, but laterally offset. The stated lateral offset may be understood in particular as a distance of the first multifunctional electrode from the second multifunctional electrode.

In this example, the electrical activation in step A includes the conduction of a heating current through the heating resistor via the first main contact and the first auxiliary contact for a first time period T1, wherein subsequently or at least somewhat concurrently, a resistance measurement between the second main contact and the second auxiliary contact is performed at the resistive track of the second multifunctional electrode for a second time period T2. Based on an amplitude and/or a temporal offset of a measurable temperature increase at the second multifunctional electrode with respect to the start and/or end of the time period T1, conclusions may be drawn concerning a flow velocity of a medium surrounding the piezoelectric resonator between the first multifunctional electrode and the second multifunctional electrode in the direction of the lateral offset.

In particular, it may be provided that the first multifunctional electrode with the heating resistor is arranged upstream from the second multifunctional electrode with the resistive track, in the flow direction of the medium that is flowing around it. That is, the medium is initially heated at the heating resistor of the first multifunctional electrode, and moves farther in the flow direction to the second multifunctional electrode. At the second multifunctional electrode the temperature of the medium is measured, from which a flow velocity of the medium may be derived.

"At least somewhat concurrently" may mean in particular that the second time period T2 starts concurrently with the first time period T1, but continues after the first time period ends, or its start is delayed by a fixed temporal offset with respect to the first time period T1.

In examples in which the piezoelectric substrate has the shape of a tuning fork with a first tine and a second tine, this method may be used particularly effectively when both multifunctional electrodes, i.e., the first and the second multifunctional electrodes, are arranged on or in the same side of the substrate, but on different tines. Due to the arrangement on different tines, the above-described lateral offset, i.e., the distance of the first multifunctional electrode from the second multifunctional electrode, may be achieved.

With regard to the lateral offset, i.e., the distance, it may likewise be conceivable for this lateral offset to be provided by the thickness of the piezoelectric substrate. The above-described measurement of a flow velocity of the medium may be performed by arranging the two multifunctional electrodes on two different, in particular oppositely arranged, surfaces of the piezoelectric substrate. For two oppositely arranged surfaces, this may involve, for example, the front side and the rear side of the piezoelectric substrate.

According to the third aspect of the invention, a multivariable sensor includes a piezoelectric resonator according to the first aspect of the invention or according to one of the stated examples thereof, as well as a control electronics system and a first switch.

The control electronics system may be designed, for example, in the form of an integrated circuit, in particular a microcontroller. It is thus possible to achieve a high level of functionality, and at the same time a compact design, robust construction, and low power consumption.

In a first switch position the first switch is configured to separately electrically connect or provide the first main contact and the first auxiliary contact of the first multifunctional electrode to the control electronics system, and in a second switch position, to insulate the first auxiliary contact from the control electronics system and/or to short-circuit the first auxiliary contact to the first main contact, while the first main contact continues to be electrically connected or provided to the control electronics system.

In this context, "electrically connect or provide" means in particular that an electrical contact is established between an electronic interface of the control electronics system and the first main contact or the first auxiliary contact.

The first switch may be provided, for example, as a separate element or component that is furnished as an electronic link between the control electronics system and the first multifunctional electrode. Alternatively, the control electronics system and the first switch may be combined in a single unit, for example a microcontroller. In such an example, the first main contact and the first auxiliary contact may be permanently connected to different electronic interfaces of the microcontroller (via different contact pins or inputs, for example). The function of the switch, i.e., the implementation of the first switch position or the second switch position, is then mapped in a purely logical manner in firmware stored in the microcontroller, also referred to below as wiring logic.

Regardless of how the first switch is configured, for example physically as a separate component or integrated as wiring logic into a microcontroller via a data link, for example, in the first switch position the control electronics system is enabled by the first switch to carry out a plurality of various measurement tasks or operating functions between the first main contact and the first auxiliary contact.

For example, the control electronics system may be configured to perform a voltage measurement and/or a resistance measurement and/or a capacitance measurement at the first multifunctional electrode, between the first main contact and the first auxiliary contact. The result of the measurement may be provided as a first measuring signal directly for the purpose of further processing in an external unit, or may initially be processed by the control electronics system itself and provided as a first processed measured value signal. In this context, "measuring signal" means a primary measuring result such as a resistance that is measured at a resistive track, while a "processed measured value signal" corresponds to a target value, such as an ambient temperature, that is calculated based on the primary measuring result.

Alternatively or additionally, if the first multifunctional electrode includes a heating resistor, the control electronics system may be configured to conduct a heating current or a test current through the first multifunctional electrode, between the first main contact and the first auxiliary contact.

In contrast, in the second switch position the control electronics system is enabled by the first switch to apply an excitation signal to the first multifunctional electrode via the first main contact, so that the first multifunctional electrode takes part in vibration excitation of the excitation section, and subsequently to switch off the excitation signal and receive a decay signal via the first main contact, and to provide the decay signal as a second measuring signal or as a second processed measured value signal. During this operation, the first auxiliary contact is either insulated from the control electronics system (which in the case of implementing the first switch as an integral part of the control electronics system in the form of a wiring logic in a microcontroller, may mean simply that no excitation signal, in particular no potential, is applied to the first auxiliary contact), or the first auxiliary contact is short-circuited to the first main contact (which in the case of implementing the first switch as an integral part of the control electronics system in the form of a wiring logic in a microcontroller, may mean simply that the same excitation signal is concurrently applied to the first auxiliary contact). In this context, "measuring signal" means a primary measuring result such as a vibration frequency, vibration amplitude, or vibration damping that is derived from the decay signal, while a "processed measured value signal" corresponds to a target value, such as a viscosity or density, that is calculated based on the primary measuring result.

In an example of the third aspect of the invention, the multivariable sensor is configured to carry out one or more of the above-mentioned methods according to the second aspect of the invention, using the control electronics system and a correspondingly designed piezoelectric resonator in each case.

It is apparent from the above discussion that the multivariable sensor is enabled by the first switch to automatedly carry out the changeover between steps A and B stated therein, which is required in the methods according to the second aspect of the invention. Namely, the first switch position corresponds to a wiring of the first multifunctional electrode that is required in respective step A of the methods – the "static operation" or the "static manner of use" – while the second switch position corresponds to a wiring that is required in respective step B of the methods – the "dynamic operation" or the "dynamic manner of use." Accordingly, the methods for use may be readily carried out by the control electronics system, for example by storing appropriate instructions in the firmware of a control electronics system designed as a microcontroller.

When the piezoelectric resonator, according to the requirements of one of the methods, in addition to the first multifunctional electrode has even further multifunctional electrodes, such as a second multifunctional electrode having a second main contact and a second auxiliary contact, the first switch may be designed to concurrently connect the contacts of all multifunctional electrodes that are present, as explained above with regard to the wiring of the first main contact and of the first auxiliary contact of the first multifunctional electrode. Alternatively, the multivariable sensor may have a separate switch for each multifunctional electrode that is present, such as a second switch for the second multifunctional electrode, a third switch for a third multifunctional electrode, and/or a fourth switch for a fourth multifunctional electrode. The above discussion of the first switch and its design and function with regard to the first multifunctional electrode analogously applies to the design and function of each further switch with regard to the multifunctional electrode associated with it in each case.

Thus, in this example of the multivariable sensor a plurality of additional measurement and operating functions may be implemented, so that it may be used in an extremely versatile and multifunctional manner.

In a further example of the third aspect of the invention, the multivariable sensor includes a housing having a process interface and a signal interface.

The process interface is configured to be connected to a measuring point at a container or a fluid line, for example at an oil tank of a mobile work machine. In addition, the process interface is closed off by a seal that prevents a medium from penetrating from the container or the fluid line into the housing of the multivariable sensor. The excitation section protrudes beyond the seal, while the base section, at least in sections, protrudes into an interior of the housing. The excitation section may thus effectively interact with a medium inside the container or the fluid line, while the base section is effectively protected from contact with the medium.

The seal may be designed as a glass feedthrough, for example, with the piezoelectric substrate being glazed into the glass feedthrough. By use of such an example, particularly reliable, long-lasting sealing of the process interface may be achieved which in particular also has high resistance to adverse chemical effects. At the same time, the glass connection to the seal ensures reinforcement of the piezoelectric substrate in the transition region between the excitation section and the base section, so that the base section is effectively shielded from vibrations and oscillations of the excitation section. When "glass" is referred to in the present context, this may be understood as an inorganic glass-like material, for example an oxidic glass (such as silicate glass, borosilicate glass, aluminosilicate glass, or some other technical glass) and/or a glass-like solder material, in particular a glass solder or a glass frit, optionally also a (partially) crystallized or devitrified glass solder.

The disclosed content of this document is not limited to the features of the above examples and/or refinements, but, rather, also includes any given combinations of these features, provided that logically they are not mutually exclusive.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1A and 1B schematically show an example of a piezoelectric resonator in perspective views, from a front side and a rear side, respectively,

FIGS. 2A and 2B schematically show different examples of the piezoelectric resonator from FIG. 1A in a sectional illustration,

FIG. 3 schematically shows a section of the piezoelectric resonator from FIG. 1A in an enlarged view,

FIG. 4A schematically shows a first example of a multivariable sensor in cross section,

FIG. 4B schematically shows a second example of a multivariable sensor in cross section, and

FIG. 5 schematically shows a further example of a piezoelectric resonator.

### DETAILED DESCRIPTION

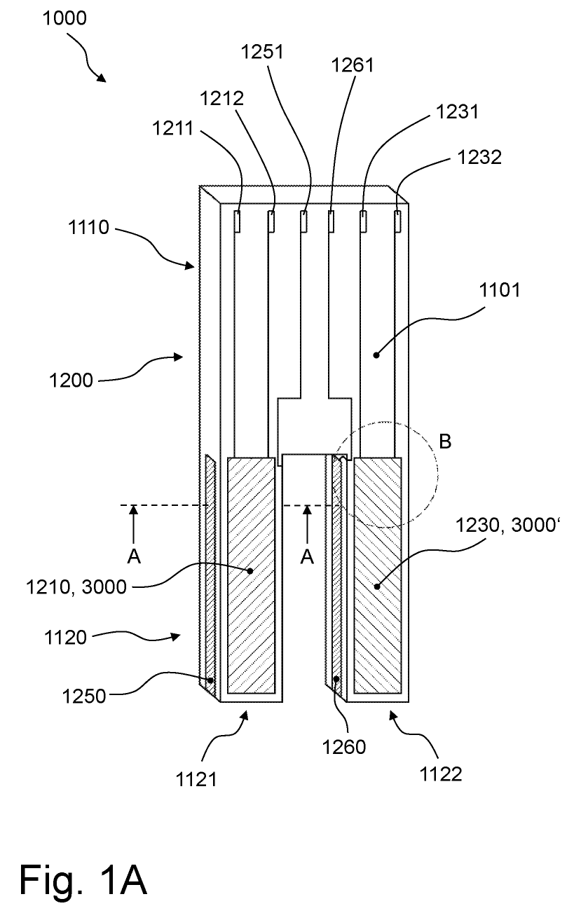

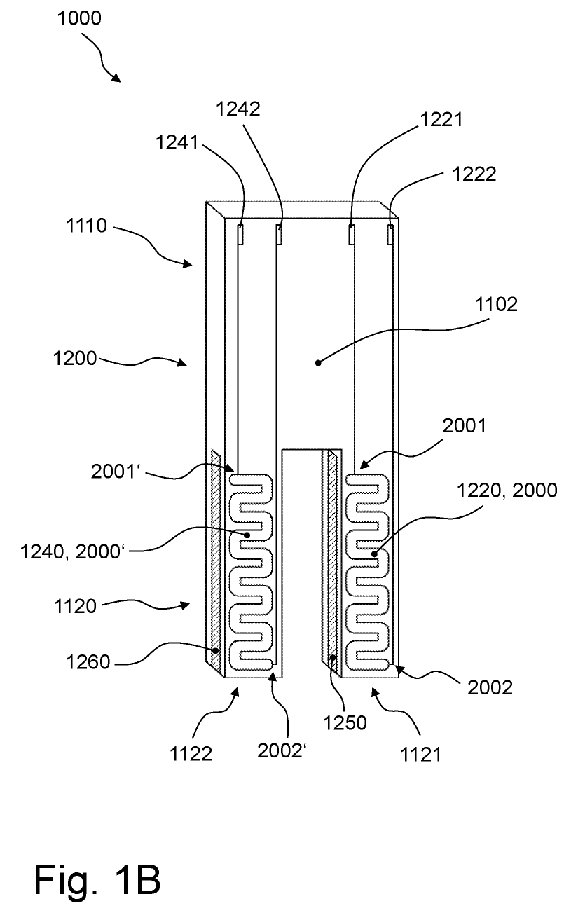

FIGS. 1A and 1B show an example of a piezoelectric resonator 1000 according to the first aspect of the invention.

The piezoelectric resonator includes a piezoelectric substrate 1100 that has the shape of a tuning fork, with an upper base section 1110, and a lower excitation section 1120 having a first tine 1121 and a second tine 1122, as well as an electrode structure 1200.

FIG. 1A illustrates the piezoelectric resonator 1000 in a front side view or front side, so that a first surface 1101 of the substrate 1100 is visible. The electrode structure 1200 includes a first multifunctional electrode 1210 that is provided at the first tine 1121, on or in the first surface 1101.

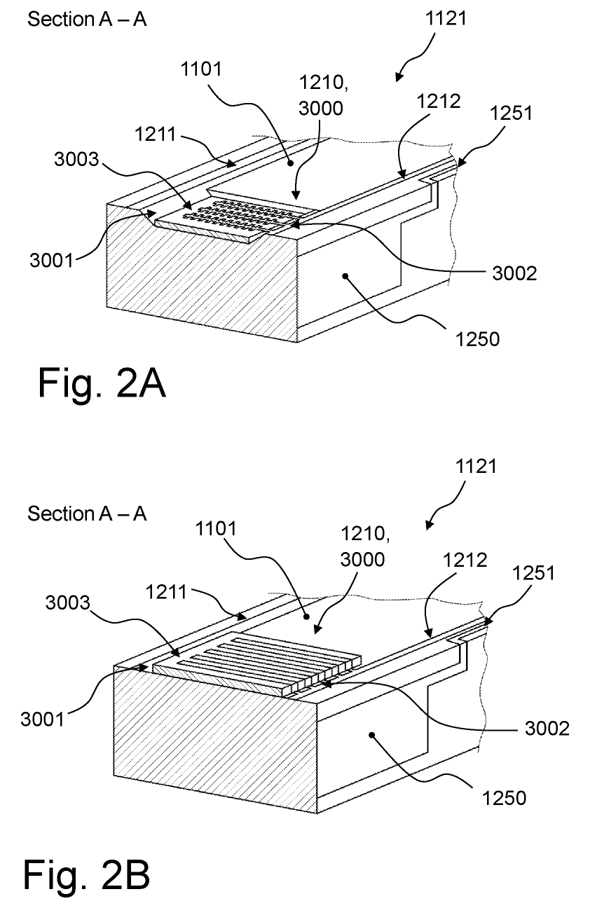

It is apparent in FIG. 2A, which shows the section A-A through the first tine 1121 in FIG. 1A in an enlarged illustration, that the first multifunctional electrode 1210 includes a capacitor 3000 or is designed as such. The capacitor 3000 includes a first capacitor electrode 3001 that forms a closed base area of the capacitor 3000. Arranged above the first capacitor electrode is a dielectric intermediate layer 3003, above which in turn a second capacitor electrode 3002 is arranged. The first capacitor electrode 3001 is electrically connected to a first main contact 1211, and the second capacitor electrode 3002 is electrically connected to a first auxiliary contact 1212, of the first multifunctional electrode. The dielectric intermediate layer 3003 has a dielectric constant that is a function of the concentration of a target medium in the surroundings of the capacitor, for example a water concentration, so that the capacitor 3000 may be used as a moisture sensor. Since the second capacitor electrode 3002 has a comb structure with lateral tines, a medium surrounding the piezoelectric resonator 1000 can come into direct contact with the dielectric intermediate layer 3003 so that it is able to effectively interact with the medium.

FIG. 2B shows an alternative example of FIG. 2A described above. An enlarged detail of the first tine 1121 is likewise illustrated. In contrast to the example shown in FIG. 2A, the capacitor 3000 in the alternative example shown in FIG. 2B is applied to a substantially flat substrate. The second capacitor electrode 3002 is covered in sections by the dielectric intermediate layer 3003. In other respects, reference may be made to the above discussion of FIG. 2A.

Furthermore, the electrode structure 1200 includes a third multifunctional electrode 1230 that is provided at the second tine 1122, on or in the first surface 1101 (see FIG. 1A).

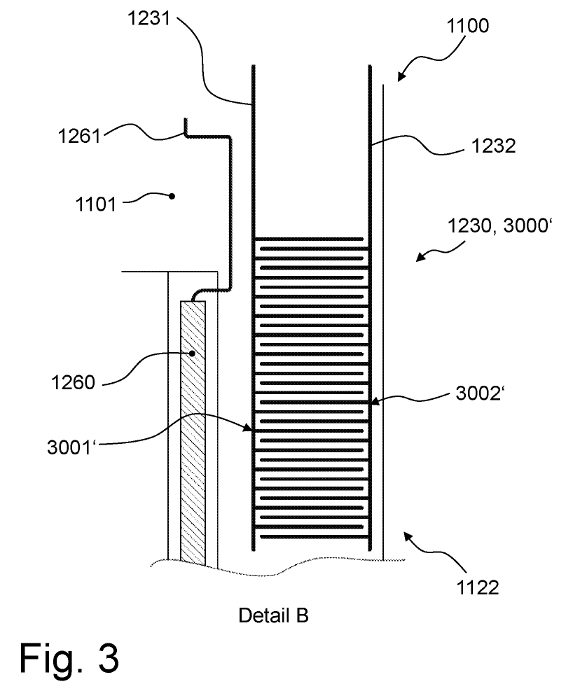

As is apparent in FIG. 3, which shows the area B marked with a circle in FIG. 1A in an enlarged detailed view, the third multifunctional electrode 1230 likewise includes a capacitor 3000' or is designed as such. The capacitor 3000' is designed as an interdigital capacitor, which means that a first capacitor electrode 3001' and a second capacitor electrode 3002' of the capacitor 3000' in each case have a comb structure and are arranged in an intermeshing manner, but are electrically insulated from one another. The first capacitor electrode 3001' is electrically connected to a third main contact 1231, and the second capacitor electrode 3002' is electrically connected to a third auxiliary contact 1232, of the third multifunctional electrode 1230.

FIG. 1B illustrates the piezoelectric resonator 1000 in a rear side view or rear side, so that a second surface 1102 of the substrate 1100 opposite from the first surface 1101 is visible. The electrode structure 1200 includes a second multifunctional electrode 1220 that is provided at the first tine 1121, on or in the second surface 1102, and a fourth multifunctional electrode 1240 that is provided at the second tine 1122, on or in the second surface 1102.

The second multifunctional electrode 1220 includes a resistive track 2000 that extends from a first end 2001 to a second end 2002. The first end 2001 is electrically connected to a second main contact 1221, and the second end 2002 is electrically connected to a second auxiliary contact 1222, of the second multifunctional electrode 1220. At the same time, the fourth multifunctional electrode 1240 likewise includes a resistive track 2000' that extends from a first end 2001' to a second end 2002'. The first end 2001' is electrically connected to a fourth main contact 1241, and the second end 2002' is electrically connected to a fourth auxiliary contact 1242, of the fourth multifunctional electrode 1240. The resistive track (2000, 2000') may, for example, have a helical or meandering course in the area between the first end (2001, 2001') and the second end (2002, 2002').

Furthermore, the electrode structure 1200 also includes a first single functional electrode 1250 that is contactable only via a first single contact 1251, and a second single functional electrode 1260 that is contactable only via a second single contact 1261. The first single functional electrode 1250 and the second single functional electrode 1260 have only a single contact, which is sufficient to apply a potential or excitation signal. To clearly express that they have only a single contact, they are in each case referred to as a "single contact." In contrast to the first multifunctional electrode 1210 (see FIG. 1A), these conventional electrodes are also referred to as "single functional" in order to clarify that they are not suited or designed for carrying out certain electronic measurement and/or operating functions that go beyond the stated simple application of a potential or an excitation signal.

While the first single functional electrode 1250 extends circumferentially across the three lateral faces of the first tine 1121, the second single functional electrode is correspondingly arranged in a circumferential extension across the three lateral faces of the second tine 1122. It is thus possible for the single functional electrodes to effectively take part in the excitation of vibrations of the tines 1121, 1122 of the excitation area 1120. For example, they may each be used as a counter potential or zero potential with respect to a respective joint excitation potential of the first and second multifunctional electrodes 1210, 1220, or of the third and fourth multifunctional electrodes 1230, 1240.

The example of the piezoelectric resonator 1000 illustrated in FIGS. 1A-3 is thus suitable for use to implement the above-mentioned methods according to the second aspect of the invention, so that all advantages stated in this context are achievable.

Furthermore, the piezoelectric resonator 1000 may be used as a component of a multivariable sensor 4000 in order to effectively achieve the advantages stated in the context of the third aspect of the invention.

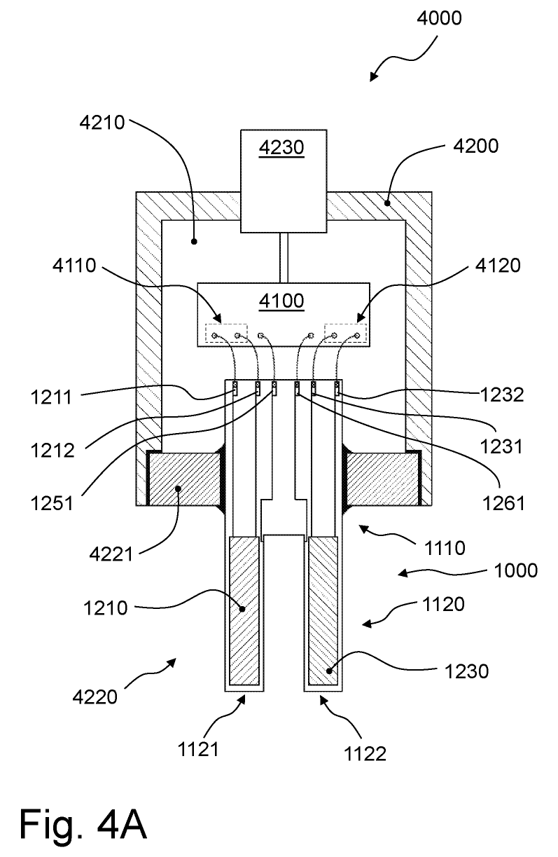

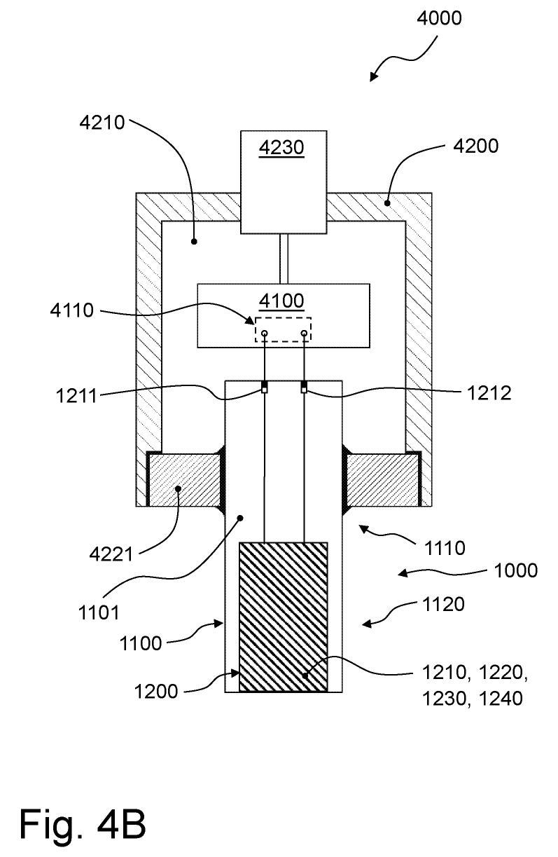

Such an example according to the third aspect of the invention is illustrated in FIG. 4A: An example of a multivariable sensor 4000 includes a piezoelectric resonator 1000 having a substrate 1100 and an electrode structure, as well as a control electronics system 4100 having a first switch 4110 and a second switch 4120 which are respectively electrically contacted to a first main contact 1211 and a first auxiliary contact 1212 of a first multifunctional electrode 1210, or to a second main contact 1221 and a second auxiliary contact 1222 of a second multifunctional electrode 1220, of the electrode structure. The control electronics system 4100 is electrically connected to the signal interface 4230, which is designed for communication and data exchange with a computer, a control room, or the like. The piezoelectric resonator 1000 may in particular have the features and designs in FIGS. 1A-3 described above.

The multivariable sensor 4000 has a housing 4200 with a process interface 4220 and a housing interior 4210, wherein a seal 4221 is provided that seals the housing interior 4210. This seal 4221 is designed as a glass molded part, with the piezoelectric resonator 1000 being glazed into a feedthrough of the seal 4221 via a glass solder connection in such a way that an excitation section 1120 protrudes from the seal and can come into contact with a medium when the multivariable sensor 4000 with its process interface 4220 is connected to a process, for example an oil tank.

FIG. 4B illustrates a further possible example of the multivariable sensor 4000. Some features, such as the housing 4200, the housing interior 4210, and the sealing of the housing 4200 with respect to the piezoelectric resonator 1000 by means of the seal 4221, are very similar, and in some cases identical, to the example in FIG. 4A.

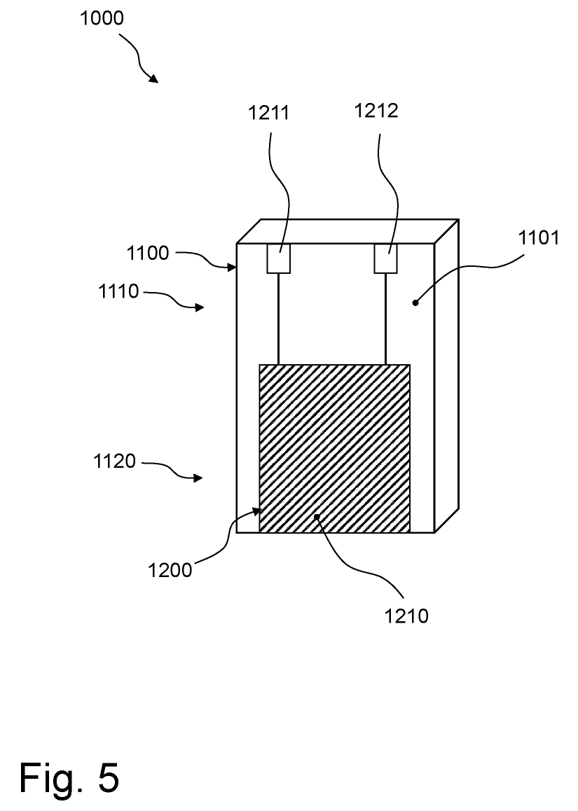

In contrast, the piezoelectric resonator 1000 does not have two separate tines, as is the case in the example according to FIG. 4A, and instead has a one-piece closed shape of the substrate 1100; in other words, only a single tine is depicted. In particular, the single tine may correspond to the example as also shown in FIG. 5. This also applies to the example of the piezoelectric resonator 1000 which may be provided at this location.

The electrode structure 1200, which may be configured as a first, second, third, or fourth multifunctional electrode (1210, 1220, 1230, 1240), is arranged on the substrate 1100. Similarly, the multifunctional electrodes may include a capacitor or a resistive track. Electrical lines on and/or inside the substrate 1100 establish connections to the two contacts, namely, the first main contact 1211 and the first auxiliary contact 1212. Starting from the main contact 1211 and the first auxiliary contact 1212, in each case a further connection to the control electronics system 4100 is established. A first switch 4110, which is also apparent in FIG. 4A, is to be regarded as an optional feature.

FIG. 5 schematically shows a further, general example of the piezoelectric resonator 1000. The piezoelectric resonator 1000 includes the piezoelectric substrate 1100 together with the base section 1110 and the excitation section 1120. In contrast to the discussion for FIGS. 1A and 1B, the piezoelectric substrate 1100 is designed as a single "tine."

Furthermore, the electrode structure 1200 is provided, which is arranged, at least in sections, at or in the excitation section 1120. The electrode structure 1200 includes the first multifunctional electrode 1210, which has the first main contact 1211 and the first auxiliary contact 1212. The example of the piezoelectric resonator just described according to FIG. 5 may in particular be used for the multivariable sensor described in FIG. 4B.

In accordance with the preceding description of the invention and with regard to the scope of the claims that follow, at this point it is noted that a particular characterization or designation of individual multifunctional electrodes in FIGS. 1A, 1B, 2A, 2B, 3, 4A, 4B, and 5 as a first multifunctional electrode 1210, as a second multifunctional electrode 1220, as a third multifunctional electrode 1230, or as a fourth multifunctional electrode 1240 is to be understood strictly as an example and/or as discretionary. This means that practically any other numbering, order, or designation would be conceivable and possible. Similarly, for example the examples of a multifunctional electrode illustrated in FIGS. 2A and 2B as a capacitor 3000/3000' are not to be construed as being limited thereto, or that this must be a or "the" first multifunctional electrode 1210; a second, third, or fourth multifunctional electrode may likewise be designed in one of the illustrated forms.

The invention is not limited to the preceding detailed examples. The invention may be modified within the scope of the claims which follow. Likewise, individual features from the subclaims may be combined with one another.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A piezoelectric resonator comprising:
a piezoelectric substrate having a base section and an excitation section; and
an electrode structure that is arranged, at least in sections, at or in the excitation section, the electrode structure comprising a first multifunctional electrode having a first main contact and a first auxiliary contact.

2. The piezoelectric resonator according to claim 1, wherein the electrode structure comprises:
a first single functional electrode having a first single contact; and
a second single functional electrode having a second single contact,
wherein the first single functional electrode and the second single functional electrode are each arranged, at least in sections, at or in the excitation section, and
wherein the first multifunctional electrode is arranged at or in the base section and/or is arranged, at least in sections, at or in the excitation section.

3. The piezoelectric resonator according to claim 1, wherein the first multifunctional electrode is arranged, at least in sections, at or in the excitation section, and wherein the electrode structure includes a first single functional electrode that has a first single contact and that is arranged, at least in sections, at or in the excitation section.

4. The piezoelectric resonator according to claim 1, wherein the first multifunctional electrode is arranged, at least in sections, at or in the excitation section, and wherein the electrode structure includes a second multifunctional electrode that is arranged, at least in sections, at or in the excitation section and that has a second main contact and a second auxiliary contact.

5. The piezoelectric resonator according to claim 4, wherein the first multifunctional electrode is arranged, at least in sections, on or in a first surface of the piezoelectric substrate, and wherein the second multifunctional electrode is arranged, at least in sections, on or in a second surface of the piezoelectric substrate opposite from the first surface.

6. The piezoelectric resonator according to claim 4, wherein the electrode structure comprises:
a third multifunctional electrode that is arranged, at least in sections, at or in the excitation section and that has a third main contact and a third auxiliary contact; and
a fourth multifunctional electrode that is arranged, at least in sections, at or in the excitation section and that has a fourth main contact and a fourth auxiliary contact.

7. The piezoelectric resonator according to claim 6, wherein the third multifunctional electrode is arranged, at least in sections, on or in a first surface of the piezoelectric substrate, and wherein the fourth multifunctional electrode is arranged, at least in sections, on or in a second surface of the piezoelectric substrate opposite from the first surface.

8. The piezoelectric resonator according to claim 6, wherein the piezoelectric substrate has a shape of a tuning fork having at least two tines, wherein the excitation section includes a first tine and a second tine, wherein the first multifunctional electrode and the second multifunctional electrode are arranged, at least in sections, in or at the first tine, and wherein the third multifunctional electrode and the fourth multifunctional electrode are arranged, at least in sections, in or at the second tine.

9. The piezoelectric resonator according to claim 1, wherein the piezoelectric substrate is made of a piezoelectric monocrystal, a quartz, or lithium niobate or includes such a piezoelectric monocrystal, and/or wherein the piezoelectric substrate has a one-piece design.

10. The piezoelectric resonator according to claim 6, wherein the first and/or second and/or third and/or fourth multifunctional electrode comprises:
a resistive track; or
a capacitor.

11. The piezoelectric resonator according to claim 10, wherein the resistive track comprises:
a temperature-dependent resistance; and/or
a resistance that is a function of the concentration of a target medium in the surroundings of the resistive track; and/or
wherein the resistive track is designed as a heating resistor and/or has a meandering shape, and/or
wherein the capacitor is designed as an interdigital capacitor or has a first capacitor electrode and a second capacitor electrode that is insulated from the first capacitor electrode by the piezoelectric substrate or a sublayer of the piezoelectric substrate, or
wherein the capacitor has a first capacitor electrode and a second capacitor electrode that is insulated from the first capacitor electrode by a dielectric intermediate layer, a dielectric constant of the dielectric intermediate layer being a function of the concentration of a target medium in the surroundings of the capacitor.

12. A method for operating the piezoelectric resonator according to claim 1, the method comprising:
performing an electrical measurement at the first multifunctional electrode between the first main contact and the first auxiliary contact, or electrically activating the first multifunctional electrode via the first main contact and the first auxiliary contact; and
applying an excitation signal to the first multifunctional electrode via the first main contact,
wherein at the first auxiliary contact, either the same excitation signal is concurrently applied or the first auxiliary contact is concurrently electrically insulated from the excitation signal.

13. The method according to claim 12, wherein the first multifunctional electrode has a capacitor, wherein the electrical measurement in the step of performing includes a capacitance measurement and/or voltage measurement, and/or wherein the first multifunctional electrode has a resistive track, and wherein the electrical measurement in the step of performing includes a resistance measurement, and/or wherein the first multifunctional electrode has a heating resistor, and wherein the electrical activation in the step of performing includes the conduction of a heating current through the heating resistor via the first main contact and the first auxiliary contact.

14. The method according to claim 12, wherein the first multifunctional electrode has a heating resistor, and the electrical activation in the step of performing includes the conduction of a heating current through the heating resistor via the first main contact and the first auxiliary contact, wherein the electrode structure has a second multifunctional electrode that is arranged, at least in sections, at or in the excitation section, and that has a second main contact and a second auxiliary contact, wherein the second multifunctional electrode is designed as a parallel plate capacitor, a first capacitor electrode being insulated from a second capacitor electrode by a dielectric intermediate layer, and a material from which the dielectric intermediate layer is made is selected such that a dielectric constant of the dielectric intermediate layer is a function of the concentration of a target medium in the surroundings of the capacitor, and wherein the first multifunctional electrode is arranged, at least in sections, on or in a first surface of the piezoelectric substrate, and the second multifunctional electrode is arranged, at least in sections, on or in a second surface of the piezoelectric substrate opposite from the first surface.

15. The method according to claim 12, wherein the first multifunctional electrode has a heating resistor, and the electrical activation in the step of performing includes the conduction of a heating current through the heating resistor via the first main contact and the first auxiliary contact, wherein the electrode structure has a second multifunctional electrode that is arranged, at least in sections, at or in the excitation section, and that has a second main contact and a second auxiliary contact, wherein the second multifunctional electrode has a resistive track with a temperature-dependent resistance, wherein the first multifunctional electrode and the second multifunctional electrode are jointly arranged on or in a surface of the piezoelectric substrate, but laterally offset, and wherein in the step of performing the heating current is conducted through the heating resistor via the first main contact and the first auxiliary contact for a first time period and subsequently or at least somewhat concurrently, and a resistance measurement between the second main contact and the second auxiliary contact is performed at the resistive track of the second multifunctional electrode for a time period T2.

16. A multivariable sensor comprising:
the piezoelectric resonator according to claim 1;
a control electronics system; and
a first switch,
wherein the first switch is configured in a first switch position to separately electrically connect or provide the first main contact and the first auxiliary contact to the control electronics system, and
wherein the first switch is configured in a second switch position, to insulate the first auxiliary contact from the control electronics system and/or to short-circuit the first auxiliary contact to the first main contact, while the first main contact is electrically connected or provided to the control electronics system.

17. The multivariable sensor according to claim 16, wherein the control electronics system is configured:
to perform an electrical measurement at the first multifunctional electrode between the first main contact and the first auxiliary contact when the first switch is in the first switch position, and to provide the result of the measurement as a first measuring signal and/or a first processed measured value signal and/or to electrically activate the first multifunctional electrode via the first main contact and the first auxiliary contact; and
to apply an excitation signal to the first multifunctional electrode, via the first main contact, when the first switch is in the second switch position so that the first multifunctional electrode takes part in vibration excitation of the excitation section and subsequently to switch off the excitation signal and receive a decay signal via the first main contact and to provide the decay signal as a second measuring signal or second processed measured value signal.

18. The multivariable sensor according to claim 17, wherein the first multifunctional electrode includes a resistive track, wherein, when the first switch is in the first switch position, the control electronics system is configured to perform a resistance measurement at the resistive track between the first main contact and the first auxiliary contact and to provide the result of the measurement as a first measuring signal and/or first processed measured value signal, and/or to conduct a heating current or a test current through the resistive track between the first main contact and the first auxiliary contact, and/or
wherein the first multifunctional electrode includes a capacitor) having a first capacitor electrode and a second capacitor electrode, the first capacitor electrode being connected to the first main contact and the second capacitor electrode is connected to the first auxiliary contact, and
wherein when the first switch is in the first switch position, the control electronics system is configured to perform a capacitance measurement and/or a voltage measurement at the capacitor between the first main contact and the first auxiliary contact and to provide the result of the measurement as a first measuring signal and/or first processed measured value signal.

19. The multivariable sensor according to claim 16, wherein the control electronics system is configured to carry out a method comprising:
performing an electrical measurement at the first multifunctional electrode between the first main contact and the first auxiliary contact, or electrically activating the first multifunctional electrode via the first main contact and the first auxiliary contact; and
applying an excitation signal to the first multifunctional electrode via the first main contact,
wherein at the first auxiliary contact, either the same excitation signal is concurrently applied or the first auxiliary contact is concurrently electrically insulated from the excitation signal.

20. The multivariable sensor according to claim 16, further comprising:
a housing having a process interface and a signal interface,
wherein the process interface is closed off by a seal,
wherein the excitation section protrudes beyond the seal and is thereby arranged outside the housing,
wherein the base section, at least in sections, protrudes into a housing interior, and
wherein the seal is designed as a glass feedthrough, and the piezoelectric substrate is glazed into the glass feedthrough.
